(19) United States
(12) Patent Application Publication
(10) Pub. No.: US 2007/0023887 A1
(43) Pub. Date: Feb. 1, 2007

(54) Multi-chip semiconductor package featuring wiring chip incorporated therein, and method for manufacturing such multi-chip semiconductor package

(75) Inventor: Satoshi Matsui, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/494,484

(22) Filed: Jul. 28, 2006

(30) Foreign Application Priority Data
Jul. 29, 2005 (JP) 2005-220652

(51) Int. Cl. H01L 23/02; H01L 21/00

(52) U.S. Cl. 257/686; 438/109; 257/E23.085

(57) ABSTRACT

In a multi-chip semiconductor package, a rectangular wiring die has a wiring pattern layer, and respective four sides of the wiring die is dimensionally identical to those of a first rectangular semiconductor die. The wiring die is mounted on the first semiconductor die so that the respective sides of the wiring die coincide with those of the first semiconductor die. A second rectangular semiconductor die has respective four sides dimensionally smaller than those of the wiring die, and the second semiconductor die is mounted on the wiring die so that the second semiconductor die occupies an inner area portion completely included in an area which are defined by the sides of said wiring die, the first and second semiconductor dies are electronically communicated with each other through the wiring pattern layer of the wiring die. A resin-molded enveloper encapsulates the dies so as to seal side surfaces of both the first semiconductor die and the wiring die and a surface of the second semiconductor die further spaced away from the wiring die.

### BACKGROUND OF THE INVENTION

1. Field of the Invention

The present invention relates to a multi-chip semiconductor package, i.e. a so-called a chip-on-chip (COC) type semiconductor package, containing at least two large scale integrated (LSI) chips or dies stacked one on top of another, and relates to a method for manufacturing such a multi-chip semiconductor package.

2. Description of the Related Art

Conventionally, an LSI logic die, a micro processor unit (MPU), an application specific integrated circuit (ASIC) or the like, and an LSI memory die, such as a dynamic random access memory (DRAM) die, a static random access memory (SRAM) or the like, have been manufactured by individual production processes, and the LSI logic die and the LSI memory die are provided on a wiring board such that electrical connections are established between the LSI logic die and the LSI memory die. However, there is no technical reason why the LSI logic die and the LSI memory die should be manufactured by individual production processes.

Thus, recently, a system-on-chip (SOC) type semiconductor package has been developed to meet the demands of higher performance, smaller and lighter size, and higher speed for various electronic tools, such as a mobile phone, a digital still camera (DSC), a digital video camera (DVC), a digital video disc (DVD), a desk top video (DTV), a multi-control unit (MCU) or the like. Namely, in the SOC type semiconductor package, both an LSI logic die and an LSI memory die are produced as one die, resulting in achievement of the demands of higher performance, smaller and lighter size, and higher speed.

On the other hand, due to progress and advances in LSI processing techniques, it is possible to produce an LSI memory die having a large capacity of 128 or 256 M bits and a plurality of pins on the order of several hundreds. Nevertheless, it is very difficult or impossible to increase the capacity of a memory to be produced in the die of the SOC type semiconductor package, to 128 or 256 N bits, in that the manufacturing yield of the SOC type semiconductor packages considerably deteriorates when a memory having the large capacity (128 or 256 N bits) is incorporated in the die of each of the SOC type semiconductor packages. Note, in general, it is said that the capacity of the memory which can be incorporated in the die of the SOC type semiconductor package, is not more than 128 M bits.

Under these circumstances, a chip-on-chip (COC) type semiconductor package has been developed, as disclosed in, for example, JP-H09-504654 and JP-2004-327474. In this SIP type semiconductor package, an LSI logic die and an LSI memory die, which are manufactured by individual production processes, are 3-dimensionally stacked one on another on a package board having a wiring pattern formed thereon, and each of the LSI logic die and the LSI memory die is suitably electrically connected to the wiring pattern of the package board. Thereafter, the LSI logic die and the LSI memory die are sealed and capsulated in a suitable enveloper.

### SUMMARY OF THE INVENTION

It has now been discovered that the above-mentioned prior art COC type semiconductor package has a problem to be solved as mentioned hereinbelow.

When a resin-molded enveloper is used as the enveloper for sealing and encapsulating the LSI logic dies and the LSI memory die, internal residual stresses are generated in the resin-molded enveloper because the resin-molded enveloper shrink when it is cured, and thus the LSI logic die and the LSI memory die may be subjected to damage due to the internal stresses. Namely, the LSI logic die and the LSI memory die are too fine and delicate to endure the internal residual stresses.

In accordance with a first aspect of the present invention, there is provided a multi-chip semiconductor package which includes a first rectangular semiconductor die, and a rectangular wiring die having a wiring pattern layer. Respective four sides of the rectangular wiring die are dimensionally identical to those of the first rectangular semiconductor die, and the rectangular wiring die is mounted on the first rectangular semiconductor die so that the respective sides of the rectangular wiring die coincide with those of the first rectangular semiconductor die. The multi-chip semiconductor package also includes a second rectangular semiconductor die having respective four sides which are dimensionally smaller than those of the rectangular wiring die, and the second rectangular semiconductor die is mounted on the rectangular wiring die so that the second rectangular semiconductor die occupies an inner area portion completely included in an area which are defined by the sides of the rectangular wiring die, and so that the first rectangular semiconductor die is electronically communicated with the second rectangular semiconductor die through the wiring pattern layer of the rectangular wiring die. The multi-chip semiconductor package further includes a resin-molded enveloper encapsulating the first rectangular semiconductor die, the rectangular wiring die and the second rectangular semiconductor die so as to seal side surfaces of both the first rectangular semiconductor die and the rectangular wiring die and a surface of the second rectangular semiconductor die further spaced away from the rectangular wiring die.

Preferably, the first rectangular semiconductor die has a wiring pattern layer formed on a surface thereof, and a plurality of through electrodes formed therein and electrically connected to the wiring pattern layer of the first rectangular semiconductor die, and the rectangular wiring die has a wiring pattern layer formed on a surface thereof, and a plurality of through electrodes formed therein and electrically connected to the wiring pattern layer of the rectangular wiring die. In this case, electrical connections are established between the wiring pattern layer of the rectangular wiring die and the wiring pattern layer of the first rectangular semiconductor die.

The mounting of the rectangular wiring die on the first rectangular semiconductor die may be carried out in a flip-chip connection manner to thereby establish electrical connections therebetween.

The second rectangular semiconductor die may be formed as a flip-chip type semiconductor die. Also, the first rectangular semiconductor die may be a large scale integrated memory die, and the second rectangular semiconductor die may be a large scale integrated logic die.

The multi-chip semiconductor package may further include a package board on a first surface of which the first rectangular semiconductor die is mounted so that electrical connections are established therebetween, and a plurality of external electrode terminals bonded to a second surface of the package board. Also, the multi-chip semiconductor package may further include a plurality of bonding wires for establishing electrical connections between the package board and the rectangular wiring die.

The multi-chip semiconductor package may further include a plurality of external electrode terminals bonded to a surface of the first rectangular semiconductor die further spaced apart from the wiring rectangular die.

When the rectangular wiring die is defined as a first rectangular wiring die, the multi-chip semiconductor package may further includes a second rectangular wiring die on a first surface of which the first rectangular semiconductor die is mounted so that electrical connections are established between the first semiconductor die and the second rectangular wiring die, and a plurality of external electrode terminals bonded to a second surface of the second rectangular wiring die.

The multi-chip semiconductor package may further include at least one third rectangular semiconductor die which is dimensionally and functionally identical to the first rectangular semiconductor die, and which is intervened between the first rectangular semiconductor die and the rectangular wiring die.

The rectangular wiring die may include a substrate, and a wiring pattern layer formed on a surface of the substrate, with the substrate having a thickness falling within a range from 20 to 30 μm, the wiring pattern layer having a thickness falling within a range from 30 to 40 μm.

Preferably, the first rectangular semiconductor die, the rectangular wiring die and the second rectangular semiconductor die includes respective substrates which have substantially the same coefficient of thermal expansion.

In accordance with a second aspect of the present invention, there is provided a method for manufacturing a multi-chip semiconductor package. In this method, a first rectangular semiconductor die is prepared, and a rectangular wiring die having a wiring pattern layer is prepared, with respective four sides of the rectangular wiring die being dimensionally identical to those of the first rectangular semiconductor die. The wiring die is mounted on the first semiconductor die so that the sides of the rectangular wiring die coincide with those of the first rectangular semiconductor die. Then, a second semiconductor die is prepared, and has respective four sides which are dimensionally smaller than those of the rectangular wiring die. The second rectangular semiconductor die is mounted on the rectangular wiring die so that the second rectangular semiconductor die occupies an inner area portion completely included in an area which are defined by the sides of the rectangular wiring die, resulting in production of a laminated die assembly containing the first rectangular semiconductor die, the rectangular wiring die and the second rectangular semiconductor die. The first rectangular semiconductor die is electrically connected to the second rectangular semiconductor die through the wiring pattern layer of the rectangular wiring die, so that the first rectangular semiconductor die is electronically communicated with the second rectangular semiconductor die through the wiring pattern layer of the rectangular wiring die. Then, the laminated die assembly is encapsulated in a resin-molded enveloper so as to seal side surfaces of both the first rectangular semiconductor die and the rectangular wiring die and a surface of the second rectangular semiconductor die further spaced away from the rectangular wiring die.

In the method, the laminated die assembly may be mounted on a first surface of a package board so that electrical connections are established between the laminated die assembly and the package board before the encapsulation of the laminated die assembly in the resin-molded enveloper. Then, a plurality of external electrode terminals may be bonded to a second surface of the package board.

Also, in the method, electrical connections may be established between the package board and the rectangular wiring die with a plurality of bonding wires before the encapsulation of the laminated die assembly in the resin-molded enveloper.

In the method, external electrode terminals may be bonded to a surface of the first rectangular semiconductor die further spaced away from the rectangular wiring die. Also, the first rectangular semiconductor die may have a plurality of through electrodes formed therein.

In accordance with a third aspect of the present invention, there is provided a method for manufacturing a plurality of multi-chip semiconductor packages, which comprises: 1) preparing a first semiconductor wafer having a plurality of first rectangular semiconductor dies formed thereon, each of the first rectangular semiconductor dies having a plurality of first through electrodes formed therein; 2) preparing a second semiconductor wafer having a plurality of rectangular wiring dies formed thereon, each of the rectangular wiring dies having a plurality of second through electrodes formed therein, the rectangular wiring dies being arranged in substantially the same manner as the first rectangular semiconductor dies, respective four sides of each of the rectangular wiring dies being dimensionally identical to those of each of the first rectangular semiconductor dies; 3) mounting the second semiconductor wafer on the first semiconductor wafer so that the respective sides of each of the rectangular wiring dies coincide with those of a corresponding first rectangular semiconductor die, and so that electrical connections are established between each of the rectangular wiring dies and the corresponding first rectangular semiconductor die through the first and second through electrodes, resulting in production of a laminated wafer assembly containing the first and second semiconductor wafers; 4) preparing a third semiconductor wafer having a plurality of second rectangular semiconductor dies formed thereon, each of the second rectangular semiconductor dies having a plurality of third through electrodes formed therein, and respective four sides which are dimensionally smaller than those of each of the rectangular wiring dies; 5) subjecting the third semiconductor wafer to a dicing process so as to be divided into a plurality of second rectangular semiconductor dies; 6) mounting each of the second rectangular semiconductor dies on a corresponding rectangular wiring die of the second semiconductor wafer so that the second rectangular semiconductor die occupies an inner area portion completely included in an area which are defined by the sides of the corresponding rectangular wiring die, and so that electrical connections are established between the corresponding rectangular wiring die and the second rectangular semiconductor die through the second and third through electrodes, whereby the first and second rectangular semiconductor dies included in the first laminated die assembly are electronically communicated with each other through the rectangular wiring die; 7) subjecting the laminated wafer assembly to a dicing process so as to be divided into a plurality of laminated die assemblies, each of which contains the first rectangular semiconductor die, the rectangular wiring die and the second rectangular semiconductor die; and 8) encapsulating each of the laminated die assemblies in a resin-molded enveloper so as to seal side surfaces of both the first rectangular semiconductor die and the rectangular wiring die and a surface of the second rectangular semiconductor die further spaced away from the rectangular wiring die.

In the third aspect of the present invention, the respective steps 4), 5), 6), 7) and 8) may be replaced with 9) subjecting the laminated wafer assembly to a dicing process so as to be divided into a plurality of first laminated die assemblies, each of which contains the first rectangular semiconductor die and the rectangular wiring die; 10) preparing a third semiconductor wafer having a plurality of second rectangular semiconductor dies formed thereon, each of the second rectangular semiconductor dies having a plurality of third through electrodes formed therein, and respective four sides which are dimensionally smaller than those of each of the rectangular wiring dies; 11) subjecting the third semiconductor wafer to a dicing process so as to be divided into a plurality of second rectangular semiconductor dies; 12) mounting each of the second rectangular semiconductor dies on the rectangular wiring die of each of the first laminated die assemblies so that the second rectangular semiconductor die occupies an inner area portion completely included in an area which are defined by the sides of the rectangular wiring die, and so that electrical connections are established between the rectangular wiring die and the second rectangular semiconductor die through the second and third through electrodes, whereby the first and second rectangular semiconductor dies included in the first laminated die assembly are electronically communicated with each other through the rectangular wiring die, resulting in production of a second laminated die assembly containing the first rectangular semiconductor die, the rectangular wiring die and the second rectangular semiconductor die; and 13) encapsulating the second laminated die assembly in a resin-molded enveloper so as to seal side surfaces of both the first rectangular semiconductor die and the rectangular wiring die and a surface of the second rectangular semiconductor die further spaced away from the rectangular wiring die.

In the third aspect of the present invention, the method may further comprise: preparing a fourth semiconductor wafer having a plurality of rectangular wiring dies formed thereon prior to the step 1), each of these wiring dies having a plurality of through electrodes formed therein; and mounting the first semiconductor wafer on the fourth semiconductor wafer. In this case, the rectangular wiring dies of the fourth semiconductor wafer are arranged in substantially the same manner as the first semiconductor dies of the first semiconductor wafer, and respective four sides of each of the rectangular wiring dies on the fourth semiconductor wafer are dimensionally identical to those of each of the rectangular wiring dies. The mounting of the fourth semiconductor wafer on the first semiconductor wafer is carried out so that the respective sides of each of the first rectangular semiconductor dies coincide with those of a corresponding rectangular wiring die on the fourth semiconductor wafer, and so that electrical connections are established between each of the first rectangular semiconductor dies and the corresponding rectangular wring die through the electrode dies of the corresponding rectangular wiring die and the first through electrodes of the first semiconductor dies.

### BRIEF DESCRIPTION OF THE DRAWINGS

The present invention will be more clearly understood from the description set forth below, as compared with the prior art, with reference to the accompanying drawings, wherein:

FIG. 1A is a partial cross-sectional view of a first prior art COC type multi-chip semiconductor package;

FIG. 1B is a schematic elevation view of a second prior art COC type multi-chip semiconductor package;

FIG. 2 is a partial cross-sectional view of a first embodiment of a COC type multi-chip semiconductor package according to the present invention;

FIG. 3 is a top plan view of an LSI memory die contained in the COC type multi-chip semiconductor package of FIG. 2;

FIG. 4A is a top plan view of a wiring die contained in the COC type multi-chip semiconductor package of FIG. 2;

FIG. 4B is a top plan view of an LSI logic die contained in the COC type multi-chip semiconductor package of FIG. 2;

FIGS. 5A through 5F are explanatory views for explaining a method for manufacturing the COC type multi-chip semiconductor package of FIG. 2;

FIG. 6 is a partial cross-sectional view corresponding to a part of FIG. 2 or 5F for explaining internal stresses generated in the COC type multi-chip semiconductor package;

FIGS. 7A and 7F are explanatory views for explaining a method for manufacturing a wiring die which may be substituted for the wiring die of the COC type multi-chip semiconductor package of FIG. 2 or 5F;

FIGS. 8A through 8H are explanatory views for explaining another method for manufacturing the COC type multi-chip semiconductor package of FIG. 2;

FIG. 9 is a partial cross-sectional view of a second embodiment of the COC type multi-chip semiconductor package according to the present invention;

FIG. 10 is a partial cross-sectional view of a third embodiment of the COC type multi-chip semiconductor package according to the present invention;

FIG. 11A is a partial cross-sectional view of a fourth embodiment of the COC type multi-chip semiconductor package according to the present invention;

FIG. 11B is an explanatory view for explaining a method for manufacturing the COC type multi-chip semiconductor package of FIG. 11A; and

FIG. 12 is a partial cross-sectional view of a fifth embodiment of the COC type multi-chip semiconductor package according to the present invention.

### DESCRIPTION OF THE PREFERRED EMBODIMENTS

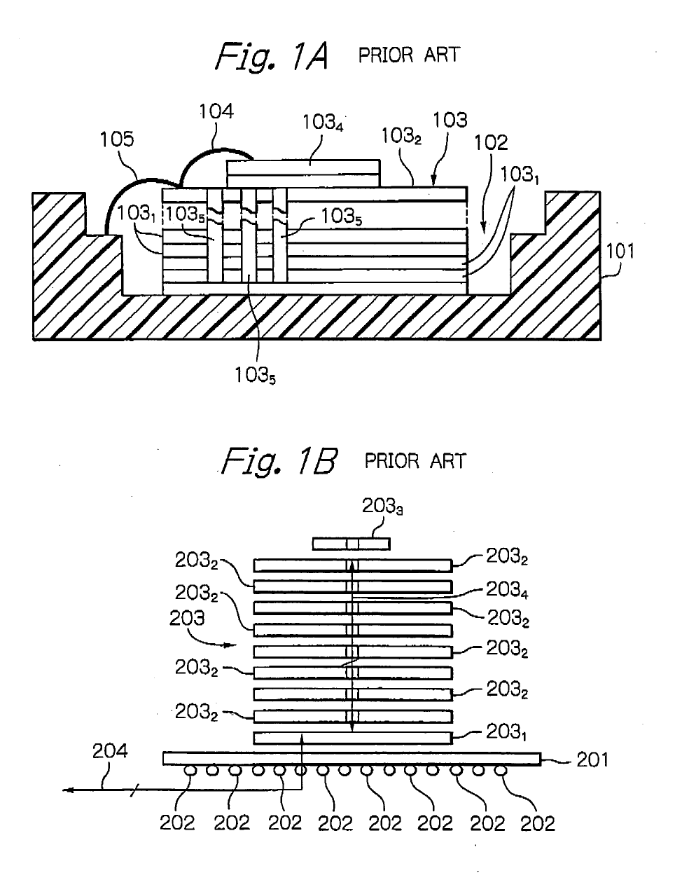

Before descriptions of embodiments of the present invention, for better understanding of the present invention, prior art COC type multi-chip semiconductor packages will be explained with reference to FIGS. 1A and 1B.

First, referring to FIG. 1A showing a first prior art COC type multi-chip semiconductor package in a partial cross-sectional view, which is disclosed in, for example, JP-H09-504654, this multi-chip semiconductor package includes a lower package portion 101 having a recess 102 formed therein, and a laminated die assembly 103 received in the recess 102. The lower package portion may be formed of a suitable plastic material or a suitable ceramic material, and has a wiring pattern (not shown in FIG. 1A) formed on an inner surface defining the recess 102. The laminated die assembly 103 contains four static random access memory (SRAM) dies 103₁ stacked in order, a wiring die or ceramic cap die 103₂ positioned above the SRAM dies 103₁, and a virtual integrated circuit (VIC) die 103₄ mounted on the ceramic cap die 103₃.

The SRAM dies 103₁ and the ceramic cap die 103₂ are electrically connected to each other by a plurality of bus strips 103₅ which are suitably provided on side faces of the stacked SRAM dies 103₁ and ceramic cap die 103₂. The VIC die 103₄ is electrically connected to the ceramic cap die 103₂ by a plurality of bonding wires, only one of which is representatively indicated by reference 104, and the ceramic cap die 103₂ is electrically connected to the aforesaid wiring pattern by a plurality of bonding wires, only one of which is representatively indicated by reference 105.

For example, when each of the SRAM dies 103₁ has a capacity of 1K bits, the VIC die 103₄ has a function for virtually regarding the four SRAM dies 103₁ as one SRAM die having 4K bits, and decodes signals read from and written in the SRAM dies 103₁.

Although not illustrated in FIG. 1A, an upper package portion is mated with the lower package portion 101, resulting in formation of an enveloper sealing and encapsulating the laminated die assembly 103. Of course, the upper package portion also may be formed of a suitable plastic material or a suitable ceramic material. When the upper package portion is mated with the lower package portion 101, i.e., when the multi-chip semiconductor package is completed, it may be supposed that the completed semiconductor package has a relatively large thickness on the order of 3 mm, because the bonding wires 104 and 105 are used to establish the electrical connections in the semiconductor package.

Referring to FIG. 1B showing a second prior art COC type multi-chip semiconductor package in a schematic elevation view, which is disclosed in, for example, JP-2004-327474, this multi-chip semiconductor package includes an interposer substrate 201 having an array of ball terminals 202 bonded to a bottom surface thereof, and a laminated die assembly 203 provided on a top surface of the interposer substrate 201. The laminated die assembly 203 contains an input/output (I/O) die 203₁ mounted on the top surface of the interposer substrate 201, eight dynamic random access memory (DRAM) dies 203₂ stacked in order on the I/O die 203₁, and a serial presence detect (SPD) die 203₃ mounted on the uppermost DRAM die 203₂. The laminated die assembly 203 is provided with a through electrode 203₄ passing therethrough, to thereby establish electrical connections between the I/O die 203₁, the DRAM dies 203₂ and the SPD die 203₃.

When the multi-chip semiconductor package is mounted on a suitable wiring board (not shown) on which a host processor is provided, it is connected to the host processor through a system data bus 204. The SPD die 203₃ stores various information data for automatically setting control conditions upon booting up the host processor.

Although not disclosed in JP-2004-327474, the laminated die assembly 203 must be sealed and encapsulated with a resin-molded enveloper, before the COC type-multi-chip semiconductor package can be obtained as a completed product. In this case, the SPD dies 203₃ are susceptible to damage due to internal residual stresses generated in the resin-molded enveloper, as already stated hereinbefore.

### First Embodiment

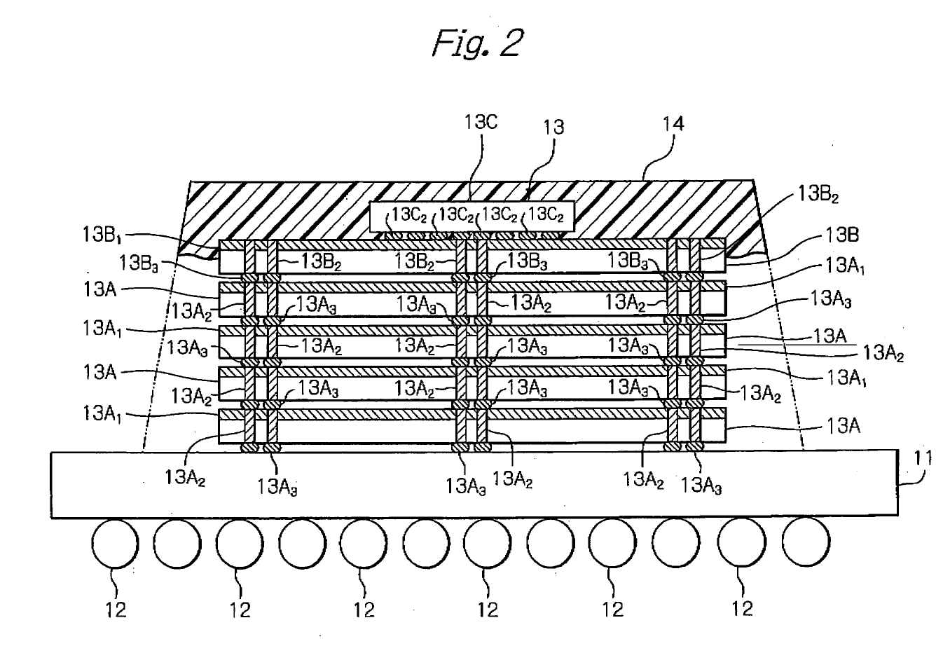

With reference to FIGS. 2, 3, 4A and 4B, a first embodiment of a COC type multi-chip semiconductor package according to the present invention will be now explained.

First, referring to FIG. 2 showing the COC type multi-chip semiconductor package in a partial cross-sectional view, this multi-chip semiconductor package includes a rectangular wiring board or package board 11 which may be composed of a suitable insulating material, such as epoxy-based resin, polyimide-based resin, polyamide-based resin, glass epoxy, ceramic or the like. Optionally, the package board 11 may be formed as an insulating tape composed of a suitable resin material, such as epoxy-based resin, polyimide-based resin, polyamide-based resin or the like. In either event, the package board 11 has wiring pattern layers (not shown) formed therein and thereon, and each of the wiring pattern layers may be composed of a suitable metal material, such as copper (Cu), aluminum (Al) or the like.

Also, the package board 11 is provided with a plurality of metal balls 12 bonded to a plurality of pads (not shown) which are formed on a bottom surface of the package board 11. Each of the metal balls 12 serves as an external electrode terminal, and is composed of a suitable metal material, such as gold (Au), copper (Cu), silver/tin alloy (Ag/Sn) or the like. In short, the package board 11 is formed for being used in a ball grid array (BGA) type semiconductor package.

Also, the multi-chip semiconductor package includes a laminated die assembly 13 provided on a top surface of the package board 11. The laminated die assembly 13 contains four rectangular LSI memory chips or dies 13A stacked one on top of another on the package board 11, a rectangular wiring chip or die 13B mounted on the uppermost one of the stacked LSI memory dies 13A, and a rectangular LSI logic chip or die 13C mounted on the wiring die 13B, and is sealed and encapsulated in a resin enveloper 14. Note, the number of the LSI memory dies 13A is variable, if necessary.

The LSI memory dies 13A are identical to each other, and each of the LSI memory dies 13A is produced by processing a monocrystalline silicon substrate, using a well-known variety of processes, such as a photolithography and etching process, a chemical vapor deposition process, a sputtering process and so on. The LSI memory dies 13A may be either a DRAM memory die having, for example, 256M bits or an SRAM memory die having, for example, 64M bits.

Each of the LSI memory dies 13A has a wiring pattern layer 13A₁ formed on a top surface thereof, a plurality of through electrodes 13A₂ formed therein so that respective top end faces of the through electrodes 13A₂ are suitably and electrically connected to the wiring pattern layer 13A₁, and a plurality of metal bumps 13A₃ bonded to respective bottom end faces of the through electrodes 13A₂.

The formation of the wiring pattern layer 13A₁ and the through electrodes 13A₂ is carried out by using well-known processes, such as a photolithography and etching process and so on. The wiring pattern layer 13A₁ and the through electrodes 13A₂ may be composed of a suitable metal material, such as copper (Cu), aluminum (Al) or the like. Each of the through electrodes 13A₂ may have a diameter falling within a range from 10 to 20 μm.

Also, each of the metal bumps 13A₃ is composed of a suitable metal material, such as gold (Au), copper (Cu), nickel (Ni), silver/tin alloy (Ag/Sn) or the like, and may have a diameter falling within a range from 10 to 30 μm, and a thickness on the order of 10 μm.

The lowermost one of the LSI memory dies 13A is mounted on the package board 11 such that the metal bumps 13A₃ are bonded to respective electrode pads (not shown) formed on the top surface of the package board 11, and the remaining three LSI memory dies 13A are mounted on the lowermost LSI memory die 13A in order such that the metal bumps 13A₂ of one LSI memory die 13A are bonded to respective top faces of the through electrode 13A₂ of the LSI memory die 13A positioned immediately below the aforesaid one LSI memory die 13A.

Preferably, the wiring die 13B is produced by processing a monocrystalline silicon substrate, using a well-known variety of processes. The wiring die 13B has a wiring pattern layer 13B₁ formed on a top surface thereof, a plurality of through electrodes 13B₂ formed therein so that respective top end faces of the through electrodes 13B₂ are suitably and electrically connected to the wiring pattern layer 13B₁, and a plurality of metal bumps 13B₃ bonded to respective bottom end faces of the through electrodes 13B₂. The wiring die 13B is mounted on the uppermost one of the LSI memory dies 13A such that the metal bumps 13B₂ of the wiring die 13B are bonded to respective top faces of the through electrode 13A₂ of the uppermost LSI memory die 13A.

Similar to the wiring pattern layers 13A₁ and the through electrodes 13A₂ of the LSI memory dies 13A, the formation of the wiring pattern layer 13B₁ and the through electrodes 13B₂ can be carried out by using well-known processes, such as a photolithography and etching process and so on, and the wiring pattern layer 13B₁ and the through electrodes 13B₂ may be composed of a suitable metal material, such as copper (Cu), aluminum (Al) or the like. Also, similar to the through electrodes 13A₂ of the LSI memory dies 13A, each of the through electrodes 13B₂ may also have a diameter falling within a range from 10 to 20 μm.

Further, similar to the metal bumps 13A₃ of the LSI memory dies 13A, each of the metal bumps 13B₃ is composed of a suitable metal material, such as gold (Au), copper (Cu), nickel (Ni), silver/tin alloy (Ag/Sn) or the like, and may have a diameter falling within a range from 10 to 30 μm, and a thickness on the order of 10 μm.

The LSI logic die 13C is produced by processing a monocrystalline silicon substrate, using well-known variable processes. The LSI logic die 13C may be a microprocessor unit (MPU), an application specific integrated circuit (ASIC) or the like. The LSI logic die 13C has a wiring pattern layer 13C₁ formed on a top surface thereof, and a plurality of metal bumps 13C₂ bonded to respective electrode pad included in the wiring pattern layer 13C₁. In short, the LSI logic die 13C is formed as a flip-chip type semiconductor device featuring the metal bumps 13C₂. Similar to the aforesaid metal bumps 13A₃ and 13B₃, each of the metal bumps 13C₂ is composed of a suitable metal material, such as gold (Au), copper (Cu), nickel (Ni), silver/tin alloy (Ag/Sn) or the like, and may have a diameter falling within a range from 10 to 30 μm, and a thickness on the order of 10 μm.

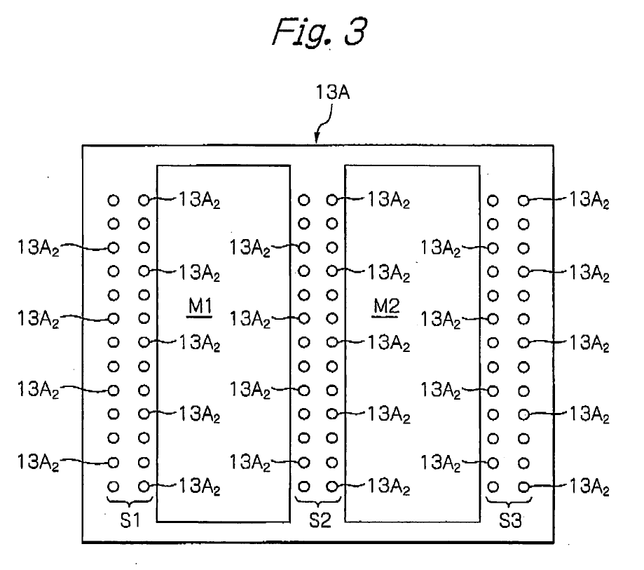

Referring to FIG. 3 which representatively shows one of the LSI memory dies 13A in a top plan view, it features a rectangular or square shape, a side length of which falls within a range, for example, from 5 to 10 mm. In this case, the silicon substrate of the LSI memory die 13A may have a thickness falling within a range from 30 to 100 μm, and a thickness of the wiring pattern layer 13A₁ is on the order of 5 μm.

The through electrodes 13A₂ are arranged in three arrays S1, and S2 and S3, which are spaced away from each other.

A memory core M1 is defined in an area between the two arrays S1 and S2, and a memory core M2 is defined in an area between the two arrays S2 and S3. Although not illustrated in FIG. 3, each of the memory core M1 and M2 contains various electronic elements, such as a plurality of memory cells, a row decoder, a column decoder and so on, and some of the various electronic elements are suitably connected to the through electrodes 13A₂ with a plurality of wiring lines included in the wiring pattern layer 13A₁. In reality, the wiring lines included in the wiring pattern layer 13A₁ cannot be seen and recognized with the naked eye because they are very fine. Namely, since the wiring lines are too fine to see, no wiring lines are illustrated in FIG. 3.

When the memory cores M1 and M2 are arranged as shown in FIG. 3, it is preferable that the through electrodes 13A₂ included in the array S2 are entirely utilized so that data are written in and read from the memory cores M1 and M2, and that the through electrodes 13A₂ included the arrays S1 and S3 are entirely utilized to carry out transmission of signals for the LSI logic die 13C.

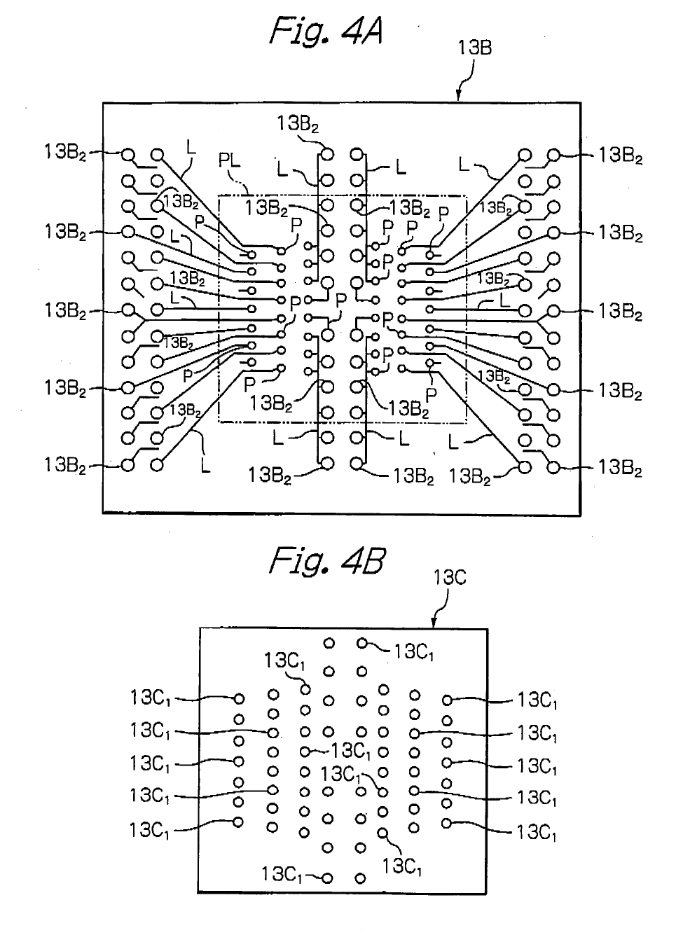

Referring to FIG. 4A which shows the wiring die 13B in a top plan view, similar to the aforesaid LSI memory die 13A (see: FIG. 3), the wiring die 13B features a rectangular or square shape, a side length of which may fall within a range from 5 to 10 mm. Also, the silicon substrate of the wiring die 13B may have a thickness falling within a range from 30 to 100 μm, and a thickness of the wiring pattern layer 13B₁ is on the order 5 μm. The production of the wiring die 13B is carried out so as to have substantially the same dimensions as the LSI memory die 13A. For example, when the LSI memory die 13A has a dimension of 5×5 mm, the wiring die 13B also has the same dimension of 5×5 mm. In short, the wiring die 13B has substantially the same extent as the LSI memory die 13A, and thus the uppermost one of the stacked four LSI memory dies 14A is completely covered with the wiring die 13B, as shown in FIG. 2.

The through electrodes 13B₂ of the wiring die 13B are arranged in substantially the same manner as the through electrodes 13A₂ of each of the LSI memory dies 13A. Thus, when the wiring die 13B is mounted on the uppermost LST memory die 12A, the through electrodes 13B₂ can be aligned with the respective through electrodes 13A₂ of the uppermost LSI memory die 12A.

In FIG. 4A, reference L indicates wiring lines included in the wiring pattern layer 13B₁, and reference P indicates electrode pads included in the wiring pattern layer 13B₁. In reality, the wiring lines L are considerably thicker than the wiring lines included in the wiring pattern layers 13A₁ of the LSI memory dies 13A, and thus can be seen and recognized with the naked eye. Although not shown in FIG. 4A, the wiring lines L and the electrode pads P may be covered with a suitable protective layer, if necessary.

Note, in FIG. 4A, reference PL indicates a square area surrounded by a phantom line, on which the flip-chip type LSI logic 13C should be mounted.

Referring to FIG. 4B which shows the flip-chip type LSI logic die 13C in a top plan view, the LSI logic die 13C features a rectangular or square shape, a side length of which may fall within a range from 2 to 7 mm. In this case, the LSI die 13A may have a thickness falling within a range from 30 to 100 μm. A dimension or extent of the LSI logic die 13C is always selected so as to be smaller than that of the wiring die 13B having substantially the same dimension as the LSI memory dies 13A. For example, when the wiring die 13B has the dimension of 5×5 mm, the LSI logic die 13C has a dimension or extent of smaller than 5×5 mm.

Note, similar to the LSI memory dies 13A, since wiring lines included in the wiring pattern layer 13C₁ are too fine to see and recognize, these wiring lines are not illustrated in FIG. 4B.

The metal bumps 13C₂ are arranged so as to form eight arrays of the metal bumps 13C₂, and the arrangement of the metal bumps 13C₂ has a mirror image relationship with respect to the arrangement of the electrode pads P and the upper end faces of the through electrodes 13B₂ included in the rectangular or square area PL (see: FIG. 4A). Thus, when the flip-chip type LSI logic die 13C is flipped over and mounted on the wiring die 13B at the rectangular or square area PL, the respective metal bumps 13C₂ are registered with and bonded on the electrode pads P and the upper end faces of the through electrodes 13B₂ included in the rectangular or square area PL.

Note, as shown in FIG. 4A, the rectangular or square area PL may be defined as an inner area portion which is completely included in the area defined by the four sides of the rectangular wiring die 13B, and which is to be occupied by the LSI logic chip 13C.

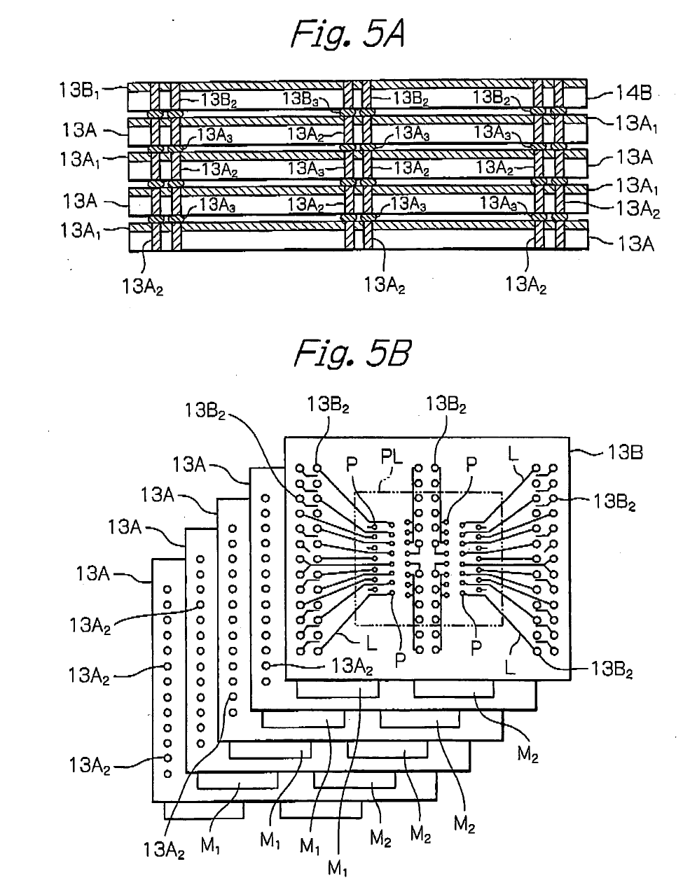

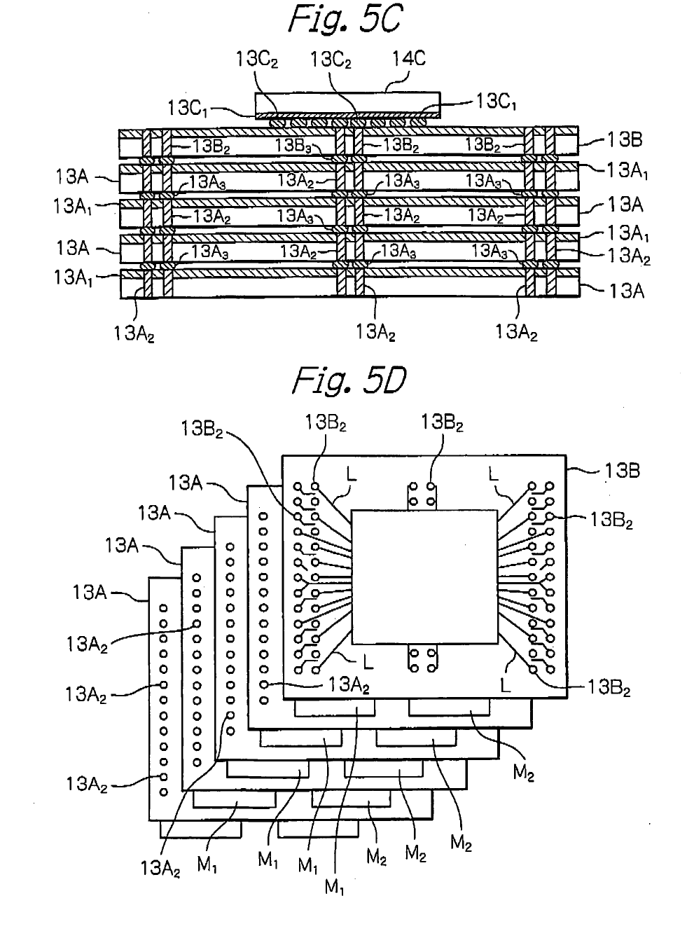

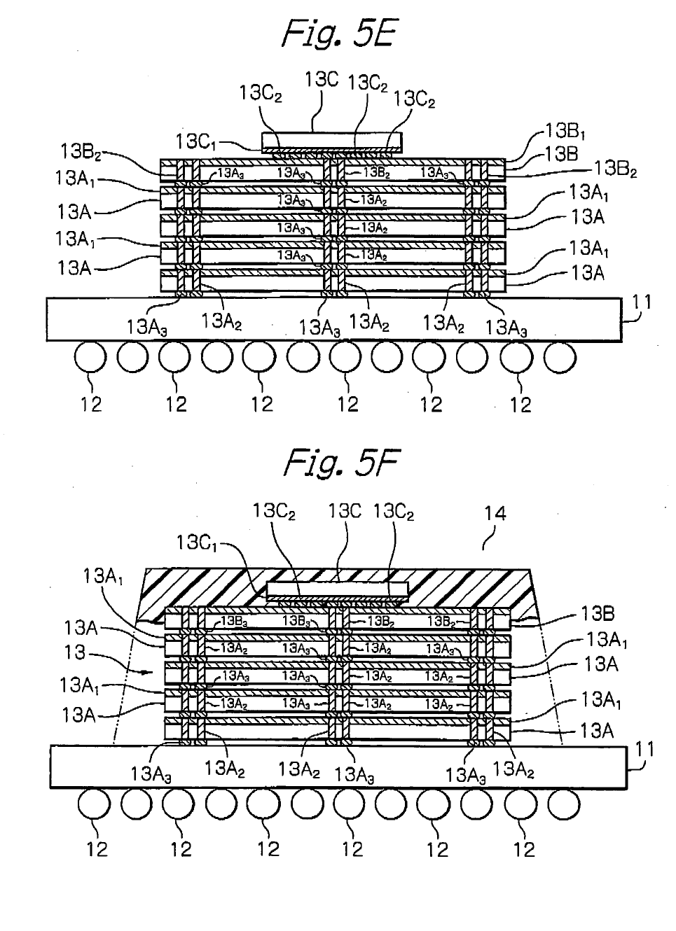

Next, with reference to FIGS. 5A through 5F, a method for manufacturing the COC type multi-chip semiconductor package of FIG. 2 will be explained below.

First, referring to FIGS. 5A and 5B which are a cross-sectional view and an exploded perspective view, respectively, the four LSI memory dies 13A are stacked one on top of another to thereby produce a laminated die assembly containing the four LSI memory dies 13A. In particular, the three LSI memory dies 13A except for the lowermost LSI memory die 13A have the metal bumps 13A₃ bonded to the bottom end faces of the through electrodes 13A₂ thereof, and are mounted in order so that the electrical connections are established between the two adjacent LSI memory dies 13A through the intermediary of the metal bumps 13A₂. Although the LSI memory dies 13A are not of a flip-chip type, it is possible to carry out the mounding of the LSI memory dies 13A in a flip-chip connection manner. Namely, the mounting of the LSI memory dies 13A may be carried out by using a conventional flip-chip bonder because they have the metal bumps 13A₃ as a flip-chip type semiconductor die.

Then, the wiring die 13B, which has the metal bumps 13B₃ bonded to the bottom end face of the through electrode 13B₂, is mounted on the uppermost one of the four LSI memory dies 13A so that the electrical connections are established between the uppermost LSI memory die 13A and the wiring die 13B through the intermediary of the metal bumps 10B₃. The mounting of the wiring die 13B on the uppermost LSI memory die 13B may be also carried out by using the conventional flip-chip bonder for the above-mentioned reason.

Next, referring to FIGS. 5C and 5D which are a cross-sectional view and an exploded perspective view, respectively, the flip-chip type LSI logic chip 13C is stacked on the laminated die assembly of FIGS. 5A and 5B to thereby produce a laminated die assembly containing the four LSI memory dies 13A and the wiring die 13B. In particular, the wiring die 13B is flipped over and mounted on the wiring die 13B at the rectangular or square area PL (see: FIG. 5D) so that the electrical connections are established between the wiring die 13B and the LSI logic die 13C. Of course, the mounting of the LSI logic die 13C on the wiring die 13B may be carried out by using the conventional flip-chip bonder.

Next, referring to FIG. 5E which is a partial cross-sectional view, the metal bumps 13A₃ are bonded to the bottom end faces of the through electrodes 13A₂ of the lowermost LSI memory die 13A, resulting in the completion of the production of the laminated die assembly 13. Then, the laminated die assembly 12 is mounted on the package board 11 so that the electrical connections are established between the package board 11 and the laminated die assembly 13 through the intermediary of the through electrodes 13A₃ of the lowermost LSI memory die 13A.

Next, referring to FIG. 5F which is identical to FIG. 2, the resin enveloper 14 is formed on the package board 11 by using a suitable resin sealing method, such as a resin transfer molding method, a resin underfilling method or the like, resulting in the completion of the production of the above-mentioned COC type multi-chip semiconductor package of FIG. 2. Note, in FIGS. 2 and 5F, for the convenience of illustration, although a thickness of the completed COC type multi-chip semiconductor package is exaggeratedly illustrated, in reality, it features a very small thickness falling within a range from 1 to 1.5 mm.

Incidentally, after the formation of the resin enveloper 14, it is cured and shrunk, and thus internal stresses are generated in the resin enveloper 14 due to the shrinkage of the resin enveloper 14.

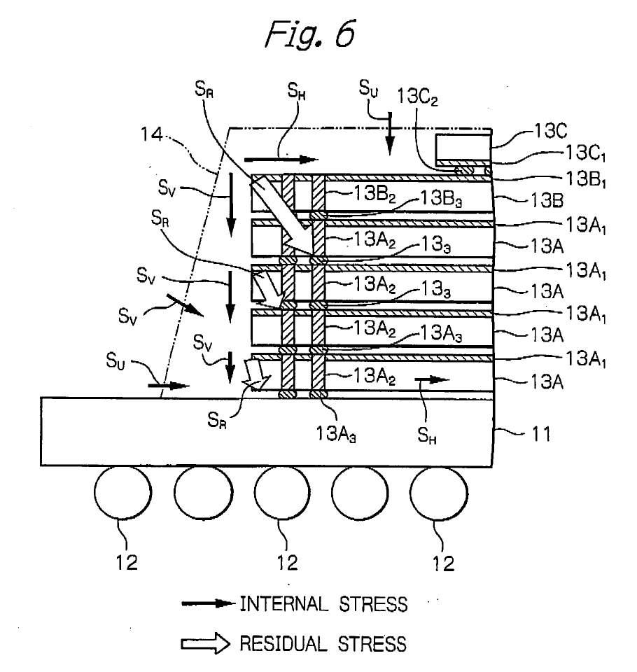

Referring to FIG. 6 corresponding to a part of FIG. 2 or FIG. 5F, a stress distribution of the internal stresses generated in the resin enveloper 14 is represented by a plurality of solid arrows. Each of the solid arrows itself represents a direction of the internal stress concerned, and a length of each of the solid arrows represents a magnitude of the internal stress concerned. A part of the internal stresses may be defined as vertical internal stresses indicated by reference S_{V}, another part of the internal stresses may be defined as horizontal internal stresses indicated by reference S_{U}, and the remaining part of the internal stresses may be defined as undersurface internal stresses indicated by reference S_{U}.

Since the resin enveloper 14 is firmly adhered to the package board 11, the vertical and horizontal internal stresses S_{V} and S_{H} are smallest in the vicinity of the package board 11, because the shrinkage of the resin enveloper 14 is minimum in the vicinity of the package board 11 due to the firm adhesion of the resin enveloper 13 to the package board 11. The vertical and horizontal internal stresses S_{V} and S_{H} become gradually larger at the locations which are farther away from the package board 11, and are largest in the vicinity of top sides of the resin enveloper 14.

The vertical and horizontal internal stresses S_{V} and S_{H} produce resultant internal stresses S_{R} represented by open arrows. Similar to the solid arrows, each of the open arrows itself represents a direction of the resultant internal stress S_{R} concerned, and a length of each of the open arrows represents a magnitude of the resultant internal stress S_{R} concerned. In short, the resultant internal stresses S_{R} are inevitably involved as residual internal stresses in the COC type multi-chip semiconductor package.

With the arrangement of the COC type multi-chip semiconductor package, the wiring die 13B prevents a direct exertion of the largest residual internal stress S_{R} on the uppermost LSI memory die 13A, because the uppermost LSI memory die 13A is completely covered with the wiring die 13B having substantially the same dimension as the LSI memory die 13A. Namely, by the wiring die 13B, the uppermost LSI memory die 13A is protected from being damaged by the largest residual internal stress S_{R}. The LSI memory die 13A is very susceptible to damage because the wiring lines included in the wiring pattern layer 13A₁ are considerably fine as stated above. On the other hand, the wiring die 13B is strong and resistant to damage in comparison with the LSI memory die 13A, because the wiring lines included in the wiring pattern layer 13B₁ are thicker than those included in the wiring pattern layer 13A₁.

Also, since the LSI logic die 13C is positioned in the vicinity of the top surface of the resin enveloper 14, the LSI logic die 13C is hardly subjected to damage because the undersurface internal stresses S_{U} are relatively small.

In short, the COC type multi-chip semiconductor package is arranged such that the LSI memory dies 13A and the LSI logic die 13C are hardly subjected to damages by the internal stresses generated in the resin enveloper 14, resulting in a decrease in production cost of the electronic packages.

When each of the LSI memory and logic dies 13A and 13C has the silicon substrate, it is preferable to produce the wiring die 13B by processing the silicon substrate, as already stated. This is because it is possible to considerably reduce thermal stresses which may be created in the COC type three-dimensional semiconductor package due to differences of thermal expansion between the LSI memory and logic dies 13A and 13C and the wiring die 13B.

Of course, it is possible to produce the wiring die 13B from another suitable substrate except for the silicon substrate, if necessary. In this case, of course, the other substrate should have substantially the same thermal expansion coefficient as the silicon substrate.

In the above-mentioned COC type multi-chip semiconductor package, the wiring die 13B serves as an interposer for establishing electrical connections between the stacked LSI memory dies 13A and the LST logic die 13C. Thus, it is possible to carry out a design of the logic LSI memory die 13C without taking a design of the LSI memory dies 13A into account. Namely, freedom of the design of the LSI logic die 13C can be considerably enhanced. Of course, the same is true for the design of the LSI memory die 13C.

For example, when the stacked LSI memory dies 13A are produced as a general-purpose die assembly, it is possible to produce the LSI logic die 13C as a custom-made die, a specific-purpose die or the like. Although depending on how the LSI logic die 13C is arranged, it is possible to suitably constitute the wiring die or interposer 13B such that electrical connections can be established between the stacked LSI memory dies 13A and the LSI logic die 13C.

As stated above, although the wiring die 13B has substantially the same dimension as the LSI memory die 13A, it is preferable that the thickness of the wiring die 13B is larger than that of the LSI memory die 13A so that the influence of the residual stresses S_{R} on the uppermost LSI memory die 13A becomes as small as possible.

As also stated above, the silicon substrate of the wiring die 13B has the thickness falling within the range from 30 to 100 μm, and the thickness of the wiring pattern layer 13B₁ is on the order of 5 μm. The production of the wiring pattern layer 13B having these dimensions is costly, because a highly precise photolithography and etching process must be used before the through electrodes 13B₂ can be formed in the relatively thick silicon substrate (30 to 100 μm), and because the formation of the relatively thin wiring pattern layer 13A₁ (5 μm) involves an expensive chemical mechanical polishing process.

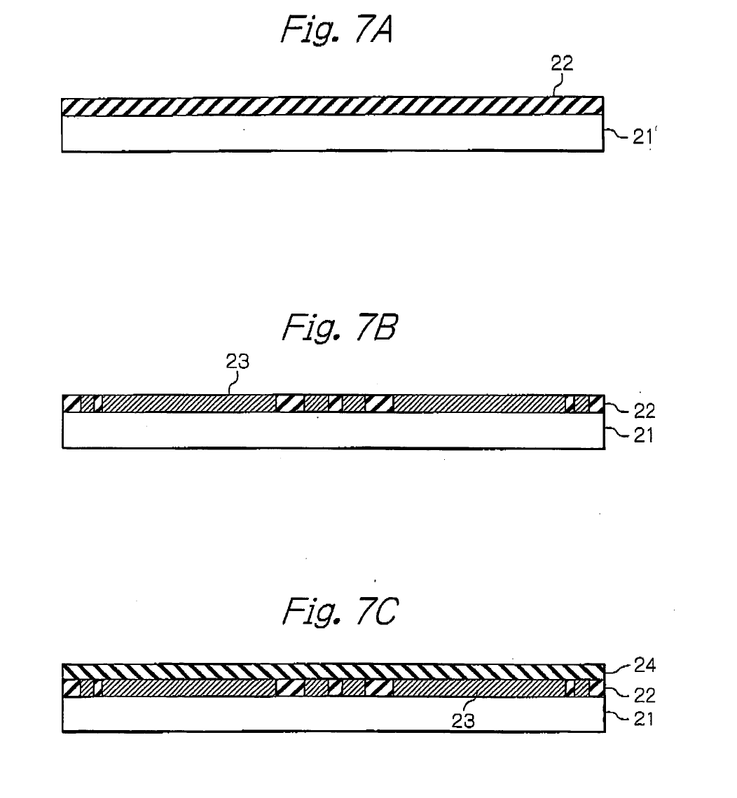

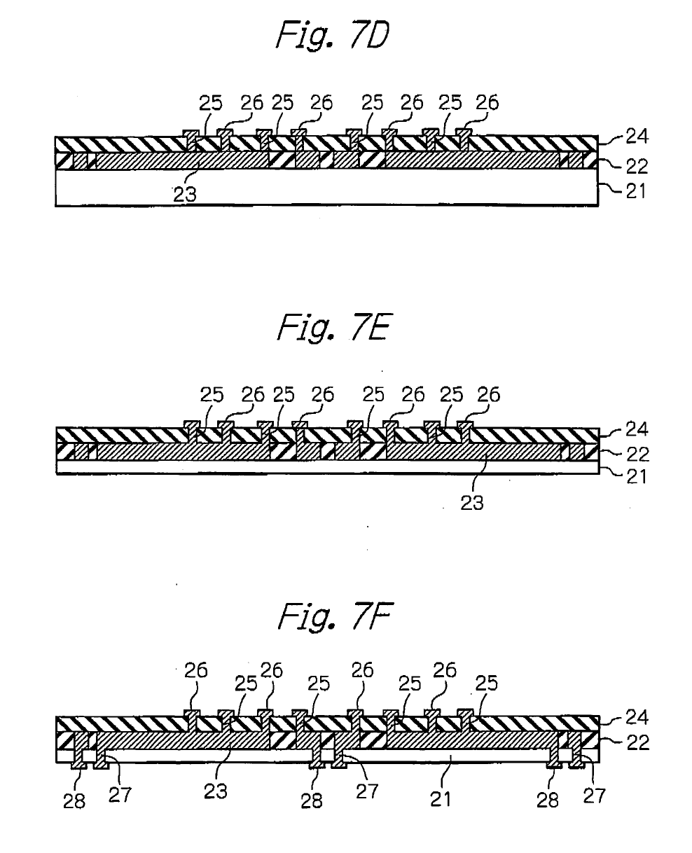

With reference to FIGS. 7A through 7F which are cross-sectional views, a method for producing an inexpensive wiring die which may be substituted for the expensive wiring die 13B is explained below.

First, referring to FIG. 7A, a monocrystalline silicon substrate 21 is prepared, and a silicon dioxide layer 22 is formed as an insulating layer on a top surface of the silicon substrate 21 by using a suitable chemical vapor deposition (CVD) process.

Next, referring to FIG. 7B, the silicon dioxide layer 22 is patterned by a photolithography and etching process, and a wiring layout structure 23 is formed in the patterned silicon dioxide layer 22 by using either an aluminum plating process or a copper plating process. Note, the photolithography and etching process used is relatively inexpensive because a high precision is not demanded in the formation of the wiring pattern layer 22, and the plating process used is also relatively inexpensive.

Next, referring to FIG. 7C, a silicon dioxide layer 24 is formed as an insulating layer on both the remaining silicon dioxide layer 22 and the wiring layout 23 by using a suitable CVD process.

Next, referring to FIG. 7D, a plurality of via plugs 25, which have respective electrode pads 26 integrally formed on top faces thereof, are formed in the silicon dioxide layer 24. In particular, holes are formed in the silicon dioxide layer 24 by using a photolithography and etching process, a metal layer is formed on the silicon dioxide layer 24 by either an aluminum plating process or a copper plating process so that the holes are filled with metal material (Al or Cu) to thereby form the via plugs 25, and the metal layer is patterned by using a photolithography and etching process to thereby form the electrode pads 26. Note that the photolithography and etching processes used also are relatively inexpensive for the same reason as stated above.

Both the silicon dioxide layer 22 having the wiring layout structure 23 and the silicon dioxide layer 24 having the via plugs 25 form a wiring pattern layer, and this wiring pattern layer (22, 24) has a thickness falling within a range from 30 to 40 μm.

Next, referring to FIG. 7E, a bottom surface of the silicon substrate 21 is subjected to a grinding process so that a thickness of the silicon substrate 21 is reduced so as to fall within a range from 20 to 30 μm.

Next, referring to FIG. 7F, a plurality of via plugs 27, which have respective electrode pads 28 integrally formed on bottom faces thereof, are formed in the silicon substrate 21. In particular, holes are formed in the silicon substrate 21 by using a photolithography and etching process, a metal layer is formed on the silicon substrate 21 by either an aluminum plating process or a copper plating process so that the holes are filled with metal material (Al or Cu) to thereby form the via plugs 27, and the metal layer is patterned by using a photolithography and etching process to thereby form the electrode pads 28, resulting in the production of the inexpensive wiring die. Note that the photolithography and etching processes used are relatively inexpensive because the silicon substrate 21 has the small thickness of less than 30 μm.

Although the inexpensive wiring die of FIG. 7F includes the thin silicon substrate 21 (less than 30 μm), the wiring pattern layer (22, 23, 24) has a sufficient thickness (30 to 40 μm) which is durable against the internal residual stresses S_{U}. Thus, the inexpensive wiring die of FIG. 7F is incorporated in the COC type 3-dimensional semiconductor package, the inexpensive wiring die can sufficiently prevent the exertion of the internal residual stresses Sᵤ on the uppermost LSI memory die 13A.

Note, although not shown in FIG. 7F, each of the holes for forming the respective via plugs 27 has an insulating layer, such as a silicon dioxide layer, formed on an inner wall thereof.

Next, with reference to FIGS. 5A through 8H, another method for manufacturing the aforesaid COC type multi-chip semiconductor package will be explained below.

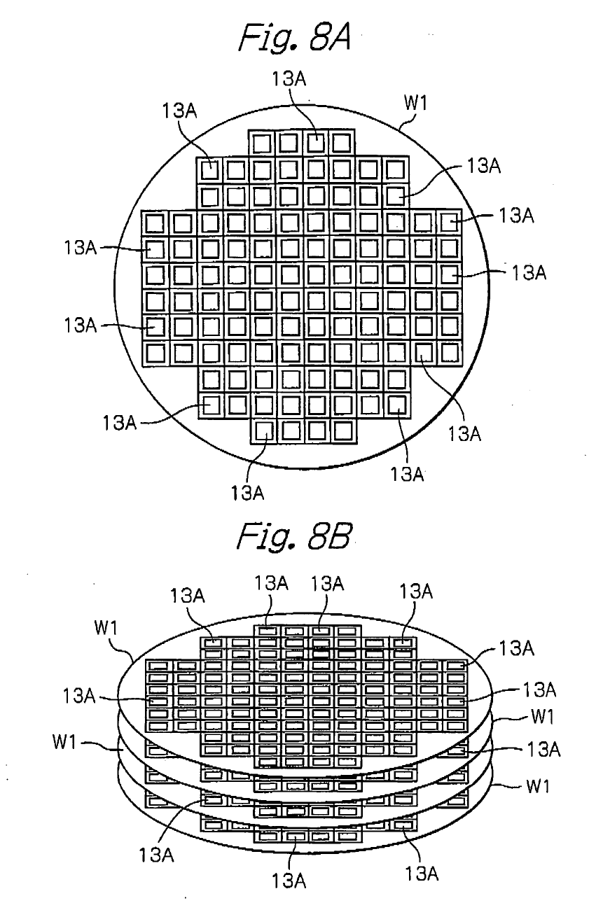

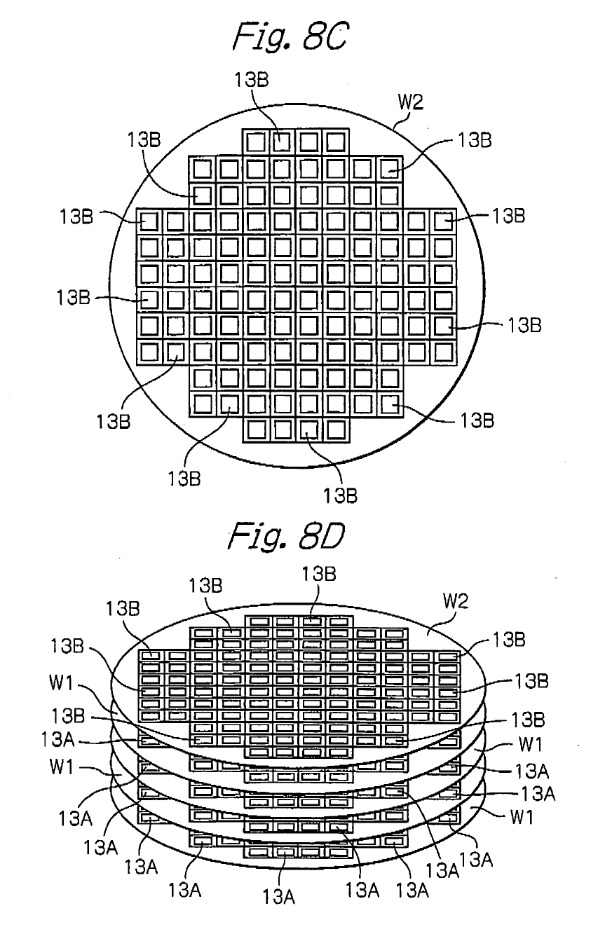

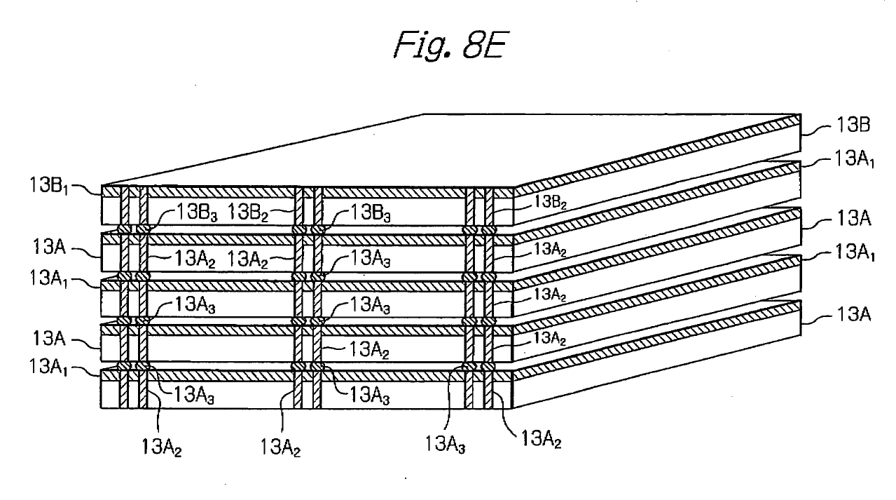

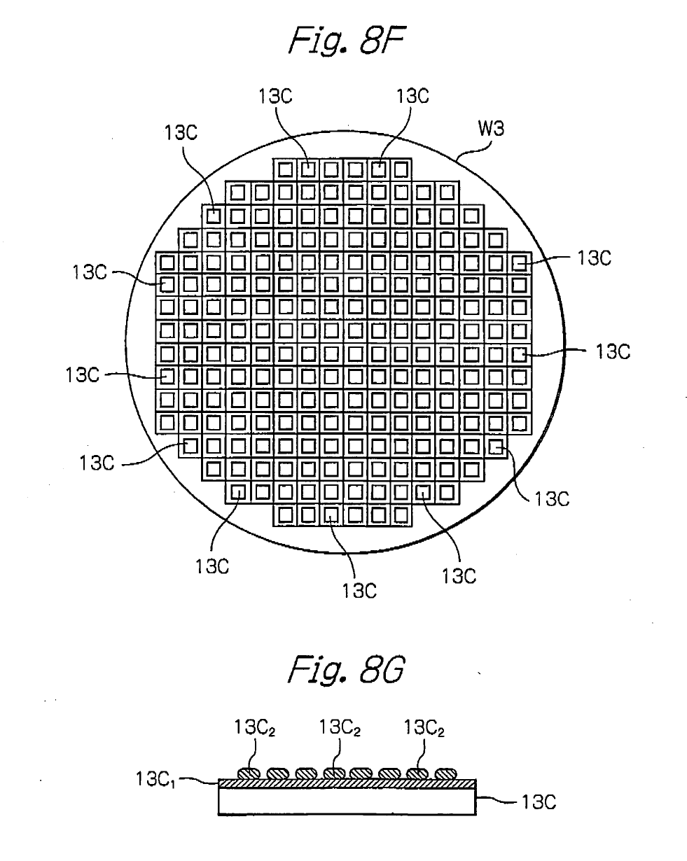

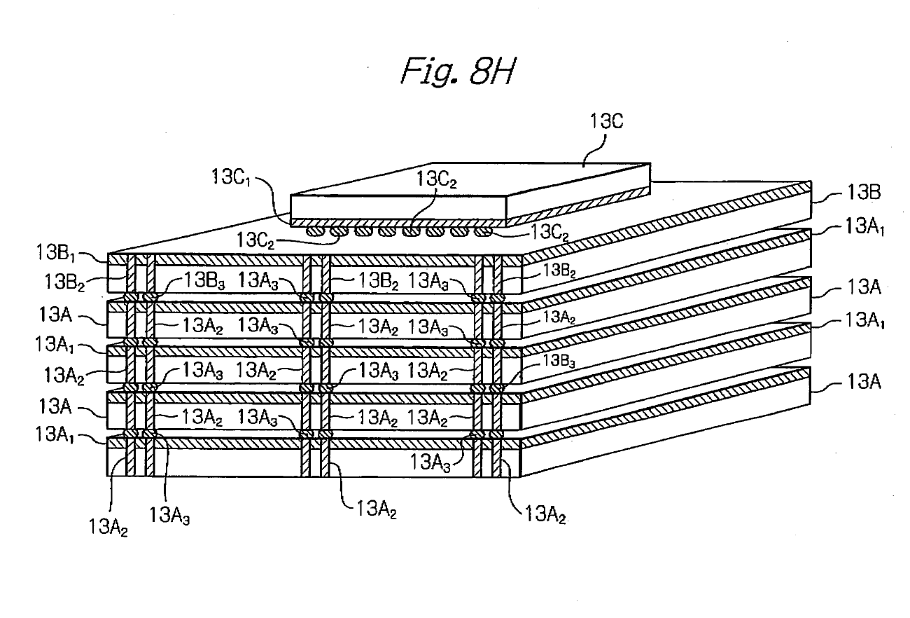

First, referring to FIG. 8A which is a top plan view, a monocrystalline silicon wafer, indicated by reference W1, has a plurality of LSI memory dies 13A formed on a top surface thereof, with each of the LSI memory dies 13A having a wiring pattern layer 13A₁ (see: FIG. 2 or FIG. 5A) formed thereon. Note, as already stated above, each of the LSI memory dies 13A is formed as either a DRAM die or an SRAM die. Then, a bottom surface of the silicon wafer W1 is subjected to a grinding process so that a thickness of the silicon wafer W1 is reduced so as to fall within a range from 30 to 100 μm. Subsequently, although not shown in FIG. 8A, a plurality of through electrodes 13A₂ (see: FIG. 2 or FIG. 5A) are formed in each of the LSI memory dies 13A.

Next, as shown in FIG. 8B which is a perspective view, the four silicon wafers W1 of FIG. 8A are prepared, and are stacked one on top of another such that the LSI semiconductor dies 13A included in one silicon wafer W1 are aligned with the respective LSI semiconductor dies 13A included in another silicon wafer W1. In particular, a plurality of metal bumps 13A₃ (see: FIG. 2 or FIG. 5A) are bonded to the bottom end faces of the through electrodes 13A₂ (see: FIG. 2 or FIG. 5A) of each of the three silicon wafers W1 except for the lowermost silicon wafer W1, and the aforesaid three silicon wafers W1 are mounted in order on the lowermost silicon wafer W1 so that electrical connections are established between the two adjacent silicon wafers W1 through the intermediary of the metal bumps 13A₃ concerned.

Next, referring to FIG. 8C which is a top plan view, another monocrystalline silicon wafer, indicated by reference W2, has a plurality of wiring dies 13B formed on a top surface thereof, and the wiring dies 13B are arranged in substantially the same manner as the LSI memory dies 13A of the silicon wafer W1, with each of the wiring dies 13B having a wiring pattern layer 13B₁ (see: FIG. 2 or FIG. 5A) formed thereon. Then, a bottom surface of the silicon wafer W2 is subjected to a grinding process so that a thickness of the silicon wafer W2 is reduced so as to fall within a range from 30 to 100 μm. Subsequently, although not shown in FIG. 8C, a plurality of through electrodes 13B₂ (see: FIG. 2 or FIG. 5A) are formed in each of the wiring dies 13B.

Next, as shown in FIG. 8D which is a perspective view, the silicon wafer W2 is stacked on the laminated wafer assembly of FIG. 8B such that the wiring dies 13B of the silicon wafer W2 are aligned with the respective LSI semiconductor dies 13A of one silicon wafer W1. In particular, a plurality of metal bumps 13B₃ (see: FIG. 2 or FIG. 5A) are bonded to the bottom end faces of the through electrodes 13B₂ (see: FIG. 2 or FIG. 5A) of the silicon wafer W2, and the silicon wafer W2 is mounted on the uppermost silicon wafer W1 of the laminated wafer assembly of FIG. 5B so that electrical connections are established between the laminated wafer assembly of FIG. 8B and the silicon wafer W2 through the intermediary of the metal bumps 13B₃.

Thereafter, the laminated wafer assembly of FIG. 8C is subjected to a dicing process so as to be divided into a plurality of laminated die assemblies.

Next, referring to FIG. 5E which representatively shows only one of the divided laminated die assemblies in a perspective view, the laminated die assembly contains the four LSI memory dies 13A, and the wiring die 13B mounted on the uppermost LSI memory die 13A thereof. Note, the laminated die assembly of FIG. 8E is corresponds to the laminated die assembly shown in FIGS. 5A and 5B.

Next, referring to FIG. 8F which is a top plan view, a monocrystalline silicon wafer, indicated by reference W3, has a plurality of LSI logic dies 13C formed on a top surface thereof, with each of the LSI logic dies 13c having a wiring pattern layer 13C₁ (see: FIG. 2 or FIG. 5C) formed thereon. Note, as already stated above, the LSI logic die 13C may be a micro processor unit (MPU), an application specific integrated circuit (ASIC) or the like. Then, a bottom surface of the silicon wafer W3 is subjected to a grinding process so that a thickness of the silicon wafer W3 is reduced so as to fall within a range from 30 to 100 μm. Subsequently, although not shown in FIG. 8F, a plurality of metal bumps 13C₂ (see: FIG. 2 or FIG. 5C) are bonded to the top surface of each of the LSI logic dies 13C.

Therefore, the silicon wafer W3 is subjected to a dicing process so as to be divided into a plurality of LSI logic dies 13.

Next, referring to FIG. 8G which representatively shows only one of the divided LSI logic dies 13C in a cross-sectional view, the wiring pattern layer of the divided logic die 13C is indicated by reference 13C₁, and the metal bumps bonded on the top surface of the divided LSI logic die 13C are indicated by reference 13C₂. Note, prior to the bonding of the metal bumps 13C₂ to the top surface of each of the LSI logic dies 13C, the dicing process of the silicon wafer W3 may be carried out.

Next, referring to FIG. 8H which is a perspective view, the divided LSI logic die 13C is flipped over and mounted on the laminated die assembly of FIG. 8E so that electrical connections are established between the wiring die 13B and the LSI logic die 13C through the intermediary of the metal bumps 13C₂, to thereby produce a laminated die assembly containing the four LSI memory dies 13A, the wiring die 13B and the LSI logic die 13C. Note, the laminated die assembly of FIG. 8H is corresponds to the laminated die assembly shown in FIGS. 5C and 5D.

Thereafter, although not shown in FIG. 8H, a plurality of metal bumps 13A₃ are bonded to the bottom end faces of the through electrodes 13A₂ of the lowermost LSI memory die 13A, and the laminated die assembly of FIG. 8H is mounted on a package board 11 (see: FIG. 5E) so that electrical connections are established between the package board 11 and the laminated die assembly concerned through the intermediary of the through electrodes 13A₃ of the lowermost LSI memory die 13A. Then, a resin enveloper 14 (see: FIG. 5F) is formed on the package board 11 by using a suitable resin sealing method, such as a resin transfer molding method, a resin underfilling method or the like, resulting in the completion of the production of the above-mentioned COC type multi-chip semiconductor package of FIG. 2.

In the aforesaid method of FIGS. 8A through 8H, although the LSI logic die 13C is mounted on the divided laminated die assembly (see: FIG. 8E), the respective LSI logic dies 13C may be mounted on the wiring dies 13B of the silicon wafer W2 prior to subjecting the laminated wafer assembly of FIG. 8C to the dicing process.

Note, of course, the wiring die as shown in FIG. 7F may be substituted for each of the wiring dies 13B formed on the silicon wafer W2 (see: FIG. 8C).

### Second Embodiment

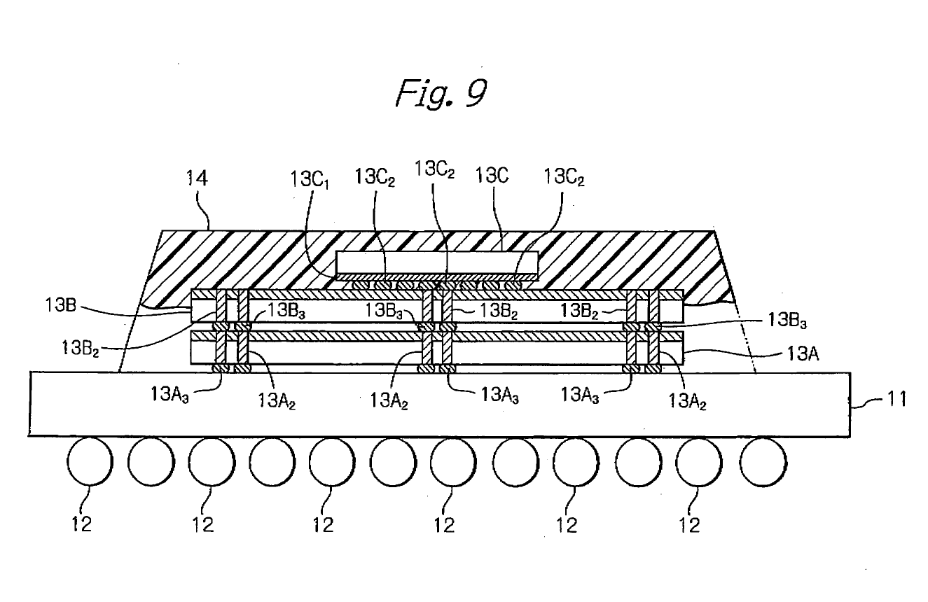

As shown in FIG. 9 which is a partial cross-sectional view, a second embodiment of the COC type multi-chip semiconductor package according to the present invention is identical to the above-mentioned first embodiment of FIG. 2 except that only one LSI memory die 13A is substituted for the laminated die assembly containing the stacked four LSI memory dies 13A.

In the second embodiment, the wiring die of FIG. 7F may be substituted for the wiring die 13B of FIG. 9.

The second embodiment may be manufactured by a similar method to that shown in either FIGS. 5A through 5F or FIGS. 8A through 8H.

### Third Embodiment

As shown in FIG. 9 which is a partial cross-sectional view, a third embodiment of the COC type multi-chip semiconductor package according to the present invention is substantially identical to the above-mentioned first embodiment of FIG. 2 except that the package board 11 (see: FIG. 2) is not used in the third embodiment. Namely, the metal balls 12 are directly bonded as external electrode terminals to electrode pads (not shown) which are formed on the bottom surface of the lowermost one of the stacked LSI memory dies 13A. The bonding of the metal balls 12 to the aforesaid electrode pads can be carried out prior to the formation of the resin enveloper 14. Otherwise, after the formation of the resin enveloper 14, the bonding of the metal balls 12 to the aforesaid electrode pads may be carried out.

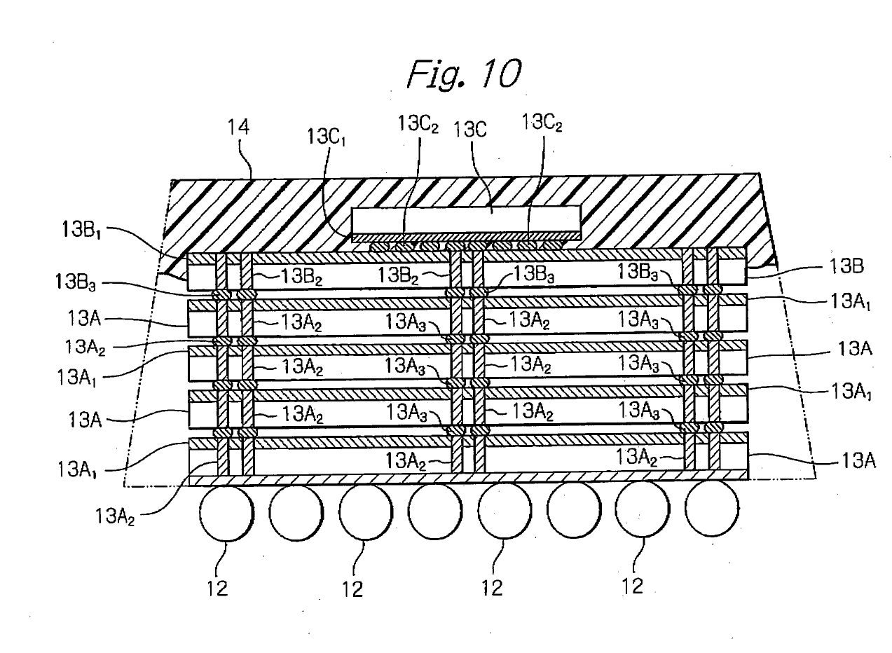

In the third embodiment, the wiring die of FIG. 7F may be substituted for the wiring die 13B of FIG. 10.

The third embodiment may be manufactured by a similar method to that shown in either FIGS. 5A through 5F or FIGS. 8A through 8H.

### Fourth Embodiment

As shown in FIG. 1A which is a partial cross-sectional view, a fourth embodiment of the COC type multi-chip semiconductor package according to the present invention is substantially identical to the above-mentioned first embodiment of FIG. 2 except that a wiring die 13D is substituted for the package board 11 (see; FIG. 2). The wiring die 13D has a wiring pattern layer 13D₁ formed on a top surface thereof, and a plurality of via plugs 13D₂ formed therein so as to be suitably connected to the wiring pattern layer 13D₁, and the metal balls 12 are bonded as external electrode terminals to respective bottom faces of the via plugs 13D₂. The bonding of the metal balls 12 to the aforesaid electrode pads can be carried out prior to the formation of the resin enveloper 14. Otherwise, after the formation of the resin enveloper 14, the bonding of the metal balls 12 to the aforesaid electrode pads may be carried out.

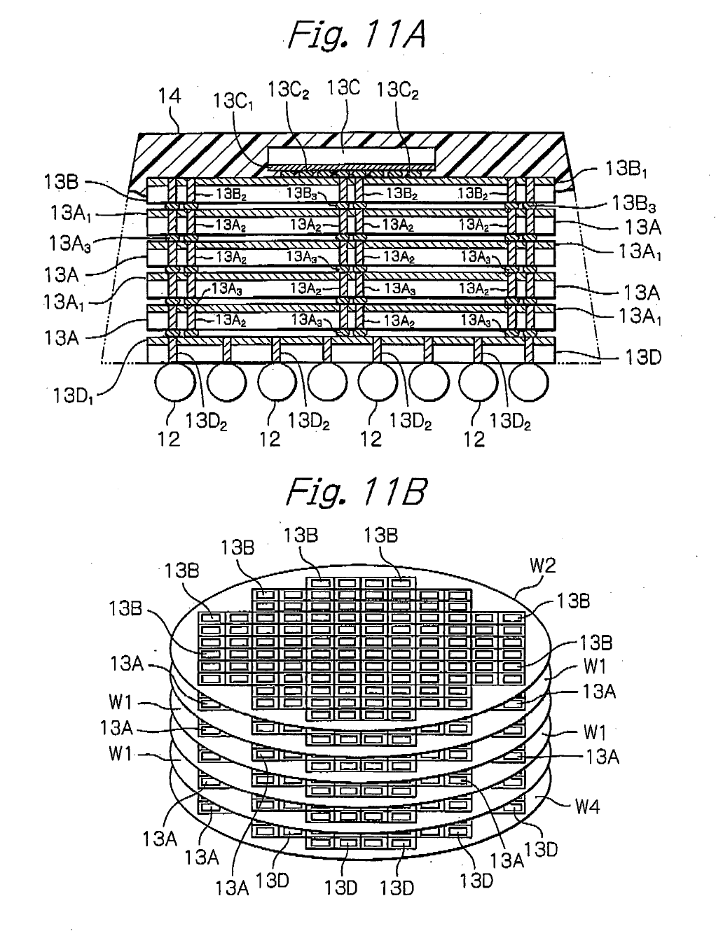

In the fourth embodiment, the wiring die of FIG. 7F may be substituted for the wiring die 13B of FIG. 11A.

The fourth embodiment may be manufactured by a similar method to that shown in FIGS. 5A through 5F.

Referring to FIG. 11B which is a perspective view, a monocrystalline silicon wafer W4 is prepared when the fourth embodiment is manufactured by a similar method to that shown in FIGS. 5A through 5H. The silicon wafer W4 has a plurality of wiring dies 13D formed on a top surface thereof, and the wiring dies 13D are arranged in substantially the same manner as the LSI memory dies 13A of the silicon wafer W1. The laminated wafer assembly containing the four silicon wafers W1 and the silicon wafer W2 is mounted on the silicon wafer W4 to thereby produce a laminated wafer assembly containing and the four silicon wafers W1, the silicon wafer W2 and the silicon wafer 13D, and this laminated wafer assembly is subjected to a dicing process so as to be divided into a plurality of laminated die assemblies, each of which contains the four LSI memory dies 13A, the wiring die 13B, and the wiring die 13D (see: FIG. 11A).

### Fifth Embodiment

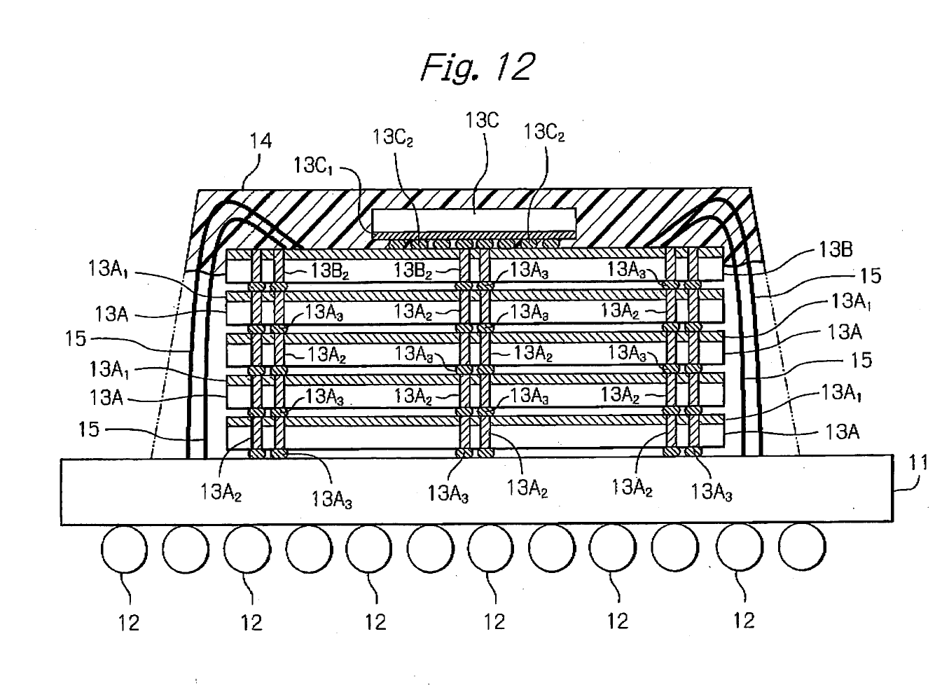

As shown in FIG. 12 which is a partial cross-sectional view, a fifth embodiment of the COC type multi-chip semiconductor package according to the present invention is substantially identical to the above-mentioned first embodiment of FIG. 2 except that additional electrical connections are established between the package board 11 and the wiring die 13B by using a plurality of bonding wires 15. Since the bonding wires 15 have a large inductance characteristic, they are unsuitable for transmission of high frequency signals (on the order of GHz), but the binding wires 15 can be used for transmission of low frequency signals.

In the above-mentioned embodiments, although the metal bumps 13A₃ are bonded to only the bottom end faces of the through electrodes 13A₂ of the LSI memory 13A, metal bumps may be bonded to the top end faces of the through electrodes 13A₂ so that the bottom metal bumps 13A₃ are connected to the top metal bumps when an LSI memory die 13A is mounted on another LSI memory. Similarly, top metal bumps may be bonded to the top end faces of the through electrodes 13B₂ of the wiring die 13B so that the metal bumps 13C₂ of the flip-chip type LSI logic die 13C are connected to the top metal bumps of the wiring die 13B.

Finally, it will be understood by those skilled in the art that the foregoing description is of preferred embodiments of the packages and methods, and that various changes and modifications may be made to the present invention without departing from the spirit and scope thereof.

1. A multi-chip semiconductor package, comprising:
a first rectangular semiconductor die;
a rectangular wiring die having a wiring pattern layer, respective four sides of said rectangular wiring die being dimensionally identical to those of said first rectangular semiconductor die, said rectangular wiring die being mounted on said first rectangular semiconductor die so that the respective sides of said rectangular wiring die coincide with those of said first rectangular semiconductor die;
a second rectangular semiconductor die having respective four sides which are dimensionally smaller than those of said rectangular wiring die, said second rectangular semiconductor die being mounted on said rectangular wiring die so that said second rectangular semiconductor die occupies an inner area portion completely included in an area which are defined by the sides of said rectangular wiring die, and so that said first rectangular semiconductor die is electronically communicated with said second rectangular semiconductor die through the wiring pattern layer of said rectangular wiring die; and
a resin-molded enveloper encapsulating said first rectangular semiconductor die, said rectangular wiring die and said second rectangular semiconductor die so as to seal side surfaces of both said first rectangular semiconductor die and said rectangular wiring die and a surface of said second rectangular semiconductor die further spaced away from said rectangular wiring die.

2. The multi-chip semiconductor package as set forth in claim 1, wherein said first rectangular semiconductor die has a wiring pattern layer formed on a surface thereof, and a plurality of through electrodes formed therein and electrically connected to the wiring pattern layer of said first rectangular semiconductor die, and wherein said rectangular wiring die has a wiring pattern layer formed on a surface thereof, and a plurality of through electrodes formed therein and electrically connected to said wiring pattern layer of said rectangular wiring die, electrical connections being established between the wiring pattern layer of said rectangular wiring die and the wiring pattern layer of said first rectangular semiconductor die.

3. The multi-chip semiconductor package as set forth in claim 2, wherein the mounting of said rectangular wiring die on said first rectangular semiconductor die is carried out in a flip-chip connection manner to thereby establish electrical connections therebetween.

4. The multi-chip semiconductor package as set forth in claim 2, wherein said second rectangular semiconductor die is formed as a flip-chip type semiconductor die.

5. The multi-chip semiconductor package as set forth in claim 1, wherein said first rectangular semiconductor die is a large scale integrated memory die, and said second rectangular semiconductor die is a large scale integrated logic die.

6. The multi-chip semiconductor package as set forth in claim 1, further comprising:
a package board on a first surface of which said first rectangular semiconductor die is mounted so that electrical connections are established therebetween; and
a plurality of external electrode terminals bonded to a second surface of said package board.

7. The multi-chip semiconductor package as set forth in claim 6, further comprising a plurality of bonding wires for establishing electrical connections between said package board and said rectangular wiring die.

8. The multi-chip semiconductor package as set forth in claim 1, further comprising a plurality of external electrode terminals bonded to a surface of said first rectangular semiconductor die further spaced apart from said wiring rectangular die.

9. The multi-chip semiconductor package as set forth in claim 1, wherein said rectangular wiring die is defined as a first rectangular wiring die, further comprising:
a second rectangular wiring die on a first surface of which said first rectangular semiconductor die is mounted so that electrical connections are established between said first semiconductor die and said second rectangular wiring die; and
a plurality of external electrode terminals bonded to a second surface of said second rectangular wiring die.

10. The multi-chip semiconductor package as set forth in claim 1, further comprising at least one third rectangular semiconductor die which is dimensionally and functionally identical to said first rectangular semiconductor die, and which is intervened between said first rectangular semiconductor die and said rectangular wiring die.

11. The multi-chip semiconductor package as set forth in claim 1, wherein said rectangular wiring die includes a substrate, and a wiring pattern layer formed on a surface of said substrate, said substrate having a thickness falling within a range from 20 to 30 μm, said wiring pattern layer having a thickness falling within a range from 30 to 40 μm.

12. The multi-chip semiconductor package as set forth in claim 1, wherein said first rectangular semiconductor die, said rectangular wiring die and said second rectangular semiconductor die includes respective substrates which have substantially the same coefficient of thermal expansion.

13. A method for manufacturing a multi-chip semiconductor package, which comprises:
preparing a first rectangular semiconductor die;
preparing a rectangular wiring die having a wiring pattern layer, respective four sides of said rectangular wiring die being dimensionally identical to those of said first rectangular semiconductor die;
mounting said wiring die on said first semiconductor die so that the sides of said rectangular wiring die coincide with those of said first rectangular semiconductor die;
preparing a second semiconductor die having respective four sides which are dimensionally smaller than those of said rectangular wiring die;
mounting said second rectangular semiconductor die on said rectangular wiring die so that said second rectangular semiconductor die occupies an inner area portion completely included in an area which are defined by the sides of said rectangular wiring die, resulting in production of a laminated die assembly containing said first rectangular semiconductor die, said rectangular wiring die and said second rectangular semiconductor die;
electrically connecting said first rectangular semiconductor die to said second rectangular semiconductor die through the wiring pattern layer of said rectangular wiring die, so that said first rectangular semiconductor die is electronically communicated with said second rectangular semiconductor die through the wiring pattern layer of said rectangular wiring die; and
encapsulating said laminated die assembly in a resin-molded enveloper so as to seal side surfaces of both said first rectangular semiconductor die and said rectangular wiring die and a surface of said second rectangular semiconductor die further spaced away from said rectangular wiring die.

14. The method as set forth in claim 13, further comprising:
preparing a package board;
mounting said laminated die assembly on a first surface of said package board so that electrical connections are established between said laminated die assembly and said package board before the encapsulation of said laminated die assembly in said resin-molded enveloper; and
bonding a plurality of external electrode terminals to a second surface of said package board.

15. The method as set forth in claim 13, further comprising establishing electrical connections between said package board and said rectangular wiring die with a plurality of bonding wires before the encapsulation of said laminated is die assembly in said resin-molded enveloper.

16. The method as set forth in claim 13, further comprising:
preparing a plurality of external electrode terminals; and
bonding said external electrode terminals to a surface of said first rectangular semiconductor die further spaced away from said rectangular wiring die.

17. The method as set forth in claim 13, wherein said first rectangular semiconductor die has a plurality of through electrodes formed therein.

18. A method for manufacturing a plurality of multi-chip semiconductor packages, which comprises:
1) preparing a first semiconductor wafer having a plurality of first rectangular semiconductor dies formed thereon, each of the first rectangular semiconductor dies having a plurality of first through electrodes formed therein;
2) preparing a second semiconductor wafer having a plurality of rectangular wiring dies formed thereon, each of said rectangular wiring dies having a plurality of second through electrodes formed therein, said rectangular wiring dies being arranged in substantially the same manner as said first rectangular semiconductor dies, respective four sides of each of said rectangular wiring dies being dimensionally identical to those of each of said first rectangular semiconductor dies;
3) mounting said second semiconductor wafer on said first semiconductor wafer so that the respective sides of each of said rectangular wiring dies coincide with those of a corresponding first rectangular semiconductor die, and so that electrical connections are established between each of said rectangular wiring dies and the corresponding first rectangular semiconductor die through said first and second through electrodes, resulting in production of a laminated wafer assembly containing said first and second semiconductor wafers;
4) preparing a third semiconductor wafer having a plurality of second rectangular semiconductor dies formed thereon, each of said second rectangular semiconductor dies having a plurality of third through electrodes formed therein, and respective four sides which are dimensionally smaller than those of each of said rectangular wiring dies;
5) subjecting said third semiconductor wafer to a dicing process so as to be divided into a plurality of second rectangular semiconductor dies;
6) mounting each of said second rectangular semiconductor dies on a corresponding rectangular wiring die of said second semiconductor wafer so that said second rectangular semiconductor die occupies an inner area portion completely included in an area which are defined by the sides of the corresponding rectangular wiring die, and so that electrical connections are established between the corresponding rectangular wiring die and said second rectangular semiconductor die through said second and third through electrodes, whereby the first and second rectangular semiconductor dies included in said first laminated die assembly are electronically communicated with each other through the rectangular wiring die;
7) subjecting said laminated wafer assembly to a dicing process so as to be divided into a plurality of laminated die assemblies, each of which contains the first rectangular semiconductor die, the rectangular wiring die and the second rectangular semiconductor die; and
8) encapsulating each of said laminated die assemblies in a resin-molded enveloper so as to seal side surfaces of both said first rectangular semiconductor die and said rectangular wiring die and a surface of said second rectangular semiconductor die further spaced away from said rectangular wiring die.

19. The method as set forth in claim 18, wherein the respective steps 4), 5), 6), 7) and 8) are replaced with the following steps 9), 10), 11), 12) and 13):
9) subjecting said laminated wafer assembly to a dicing process so as to be divided into a plurality of first laminated die assemblies, each of which contains the first rectangular semiconductor die and the rectangular wiring die;
10) preparing a third semiconductor wafer having a plurality of second rectangular semiconductor dies formed thereon, each of said second rectangular semiconductor dies having a plurality of third through electrodes formed therein, and respective four sides which are dimensionally smaller than those of each of said rectangular wiring dies;
11) subjecting said third semiconductor wafer to a dicing process so as to be divided into a plurality of second rectangular semiconductor dies;
12) mounting each of said second rectangular semiconductor dies on the rectangular wiring die of each of said first laminated die assemblies so that said second rectangular semiconductor die occupies an inner area portion completely included in an area which are defined by the sides of said rectangular wiring die, and so that electrical connections are established between said rectangular wiring die and said second rectangular semiconductor die through said second and third through electrodes, whereby the first and second rectangular semiconductor dies included in said first laminated die assembly are electronically communicated with each other through the rectangular wiring die, resulting in production of a second laminated die assembly containing the first rectangular semiconductor die, the rectangular wiring die and the second rectangular semiconductor die; and
13) encapsulating said second laminated die assembly in a resin-molded enveloper so as to seal side surfaces of both said first rectangular semiconductor die and said rectangular wiring die and a surface of said second rectangular semiconductor die further spaced away from said rectangular wiring die.

20. A method as set forth in claim 18, further comprising:
preparing a fourth semiconductor wafer having a plurality of rectangular wiring dies formed thereon prior to the step 1), each of these wiring dies having a plurality of through electrodes formed therein; and
mounting said first semiconductor wafer on said fourth semiconductor wafer,
wherein the rectangular wiring dies of said fourth semiconductor wafer are arranged in substantially the same manner as the first semiconductor dies of said first semiconductor wafer, respective four sides of each of the rectangular wiring dies on said fourth semiconductor wafer being dimensionally identical to those of each of said rectangular wiring dies, the mounting of said fourth semiconductor wafer on said first semiconductor wafer being carried out so that the respective sides of each of said first rectangular semiconductor dies coincide with those of a corresponding rectangular wiring die on said fourth semiconductor wafer, and so that electrical connections are established between each of said first rectangular semiconductor dies and the corresponding rectangular wring die through said electrode dies of the corresponding rectangular wiring die and the first through electrodes of said first semiconductor dies.
